(19) United States
(12) Patent Application Publication
(10) Pub. No.: US 2014/0127394 A1
(43) Pub. Date: May 8, 2014

(54) Reducing Glitching In An Ion Implanter

(71) Applicant: Varian Semiconductor Equipment Associates, Inc., Gloucester, MA (US)

(72) Inventors: George M. Gammel, Marblehead, MA (US); Brant S. Binns, Beverly, MA (US); Piotr R. Lubicki, Peabody, MA (US); Bon-Woong Koo, Andover, MA (US); Richard M. White, Newmarket, NH (US); Kevin M. Daniels, Lynnfield, MA (US)

(21) Appl. No.: 14/063,495

(22) Filed: Oct. 25, 2013

Related U.S. Application Data
(60) Provisional application No. 61/723,604, filed on Nov. 7, 2012.

(51) Int. Cl. C23C 14/54; C23C 14/48

(52) U.S. Cl. CPC C23C 14/54; C23C 14/48
USPC 427/8; 427/523

(57) ABSTRACT

Methods of reducing glitch rates within an ion implanter are described. In one embodiment, a plasma-assisted conditioning is performed, wherein the bias voltage to the extraction electrodes is modified so as to inhibit the formation of an ion beam. The power supplied to the plasma generator in the ion source is increased, thereby creating a high density plasma, which is not extracted by the extraction electrodes. This plasma extends from the arc chamber through the extraction aperture. Energetic ions then condition the extraction electrodes. In another embodiment, a plasma-assisted cleaning is performed. In this mode, the extraction voltage applied to the arc chamber body is modulated between two voltages so as to clean both the extraction electrodes and the faceplate of the arc chamber body.

This application claims priority of U.S. Provisional Patent Application Ser. No. 61/723,604, filed Nov. 7, 2012, the disclosure of which is incorporated herein by reference in its entirety.

### FIELD

This disclosure relates to ion implantation and, more particularly, to reducing glitching in an ion implanter.

### BACKGROUND

Ion implantation is a standard technique for introducing conductivity-altering impurities into a workpiece. A desired impurity material is ionized in an ion source, the ions are accelerated to form an ion beam of prescribed energy, and the ion beam is directed at the surface of the workpiece. The energetic ions in the ion beam penetrate into the bulk of the workpiece material and are embedded into the crystalline lattice of the workpiece material to form a region of desired conductivity.

Two concerns of the solar cell manufacturing industry are manufacturing throughput and cell efficiency. Cell efficiency measures the amount of energy converted into electricity. Higher cell efficiencies may be needed to stay competitive in the solar cell manufacturing industry. However, manufacturing throughput cannot be sacrificed at the expense of increased cell efficiency.

Ion implantation has been demonstrated as a viable method to dope solar cells. Use of ion implantation removes process steps needed for existing technology, such as diffusion furnaces. For example, a laser edge isolation step may be removed if ion implantation is used instead of furnace diffusion because ion implantation will only dope the desired surface. Besides removal of process steps, higher cell efficiencies have been demonstrated using ion implantation. Ion implantation also offers the ability to perform a blanket implant of an entire surface of a solar cell or a selective (or patterned) implant of only part of the solar cell. Selective implantation at high throughputs using ion implantation avoids the costly and time-consuming lithography or patterning steps used for furnace diffusion. Selective implantation also enables new solar cell designs. Any improvement to manufacturing throughput of an ion implanter or its reliability would be beneficial to solar cell manufacturers worldwide. This may accelerate the adoption of solar cells as an alternative energy source.

“Glitches” may occur during the ion implantation process. A glitch is defined as a sudden degradation in the beam quality during an ion implantation operation, typically due to a variation in an operating voltage. Such a glitch is typically caused by interactions between components along the beam path, which affect one or more operating voltages and can be caused at various locations along the beam path. For example, ion implanters generally employ several electrodes along this beam path, which accelerate the beam, decelerate the beam, or suppress spurious streams of electrons that are generated during operation. Each of these electrodes is maintained at a predetermined voltage. Often, electrodes of different voltage are located near each other and therefore arcing may occur between electrodes. Generally, arcing occurs across acceleration gaps, deceleration gaps, or suppression gaps, although arcing may occur elsewhere. Interaction between, for example, a source extraction voltage, source suppression voltage, and source beam current may cause a glitch. These glitches may be detected as a sharp change in the current from one of the power supplies. If the implantation is interrupted or affected by a glitch, the implanted solar cell or other workpiece may be negatively affected or even potentially rendered unusable. For example, a solar cell may have a lower efficiency due to the lower implanted dose caused by a glitch.

Use of a fluoride-containing gas during implantation may limit throughput due to this glitching. With a fluoride-containing gas, such as BF₃, this glitching may include arcing at the various electrodes in the implanter, such as between the ion source and the extraction electrodes. Any method that reduces glitching in an ion implanter will increase throughput and improve the quality of the implanted workpieces.

### SUMMARY

Methods of reducing glitch rates within an ion implanter are described. In one embodiment, a plasma-assisted conditioning is performed, wherein the bias voltage to the extraction electrodes is modified so as to inhibit the formation of an ion beam. The power supplied to the plasma generator in the ion source is increased, thereby creating a high density plasma, which is not extracted by the extraction electrodes. This plasma extends from the arc chamber through the extraction aperture. Energetic ions then condition the extraction electrodes. In another embodiment, a plasma-assisted cleaning is performed.

In this mode, the extraction bias voltage applied to the arc chamber body is modulated between two voltages so as to clean both the extraction electrodes and the faceplate of the arc chamber body.

In one embodiment, a method of reducing a glitch rate of an ion implanter, is disclosed. The method comprising generating a plasma in an arc chamber, defined by an arc chamber body; extracting plasma from the arc chamber body through an extraction aperture disposed on a faceplate of the arc chamber to an extraction region outside the arc chamber; and directing ions within the plasma disposed in the extraction region toward the faceplate.

In a second embodiment, a method of reducing a glitch rate of an ion implanter is disclosed. This method comprises generating a plasma in an arc chamber defined by an arc chamber body, the arc chamber body further comprising a faceplate; extracting first ions within the plasma disposed in the arc chamber through an extraction aperture in the faceplate; directing the first ions through an aperture of a suppression electrode, the suppression electrode disposed proximate to the arc chamber body; and extracting a cleaning plasma generated in the arc chamber through the extraction aperture into an extraction region interposed between the faceplate and the suppression electrode.

In a third embodiment, a method of reducing a glitch rate of an ion implanter is disclosed. The method comprises generating a cleaning plasma in an arc chamber, defined by an arc chamber body, the arc chamber body further comprising a faceplate; extracting the cleaning plasma generated within the arc chamber into an extraction region interposed between the arc chamber body and a suppression electrode; and impacting a surface of at least one of the faceplate and the suppression electrode with first ions from the cleaning plasma disposed in the extraction region. In a further embodiment, the method further comprises generating a plasma within the arc chamber; extracting second ions in the plasma disposed within the arc chamber through an extraction aperture in the faceplate; and directing the second ions from the arc chamber through an aperture of the suppression electrode, the suppression electrode disposed proximate to the faceplate, wherein the first ions and the second ions contain different species.

### BRIEF DESCRIPTION OF THE DRAWINGS

For a better understanding of the present disclosure, reference is made to the accompanying drawings, which are incorporated herein by reference and in which:

FIG. 1 are charts representing glitch rate, throughput, and number of wafers processed over time in a first embodiment;

FIG. 2 are charts representing glitch rate, throughput, and number of wafers processed over time in a second embodiment;

FIG. 3A illustrates some components used in a representative ion implanter;

FIG. 3B illustrates the ion implanter of FIG. 3A during a plasma-assisted conditioning cycle;

FIG. 4A illustrates the ion implanter of FIG. 3A during a plasma-assisted cleaning cycle according to a first embodiment; and

FIG. 4B illustrates the ion implanter of FIG. 3A during a plasma-assisted cleaning cycle according to a second embodiment.

### DETAILED DESCRIPTION

These methods are described herein in connection with an ion implanter. However, these methods can be used with other systems and processes involved in semiconductor manufacturing or other systems that use a plasma or an ion beam. Thus, the disclosure is not limited to the specific embodiments described below.

As material builds up on extraction electrodes within an ion implanter, the glitch rate (or frequency of glitching) increases. Material buildup may “roughen” the surface of the electrode. This roughened surface may increase the local electrostatic field, which may lead to arcing. In addition, material buildup may change the electrical properties of the electrode's surface, for example, by making it less conductive, which may be conducive to arcing.

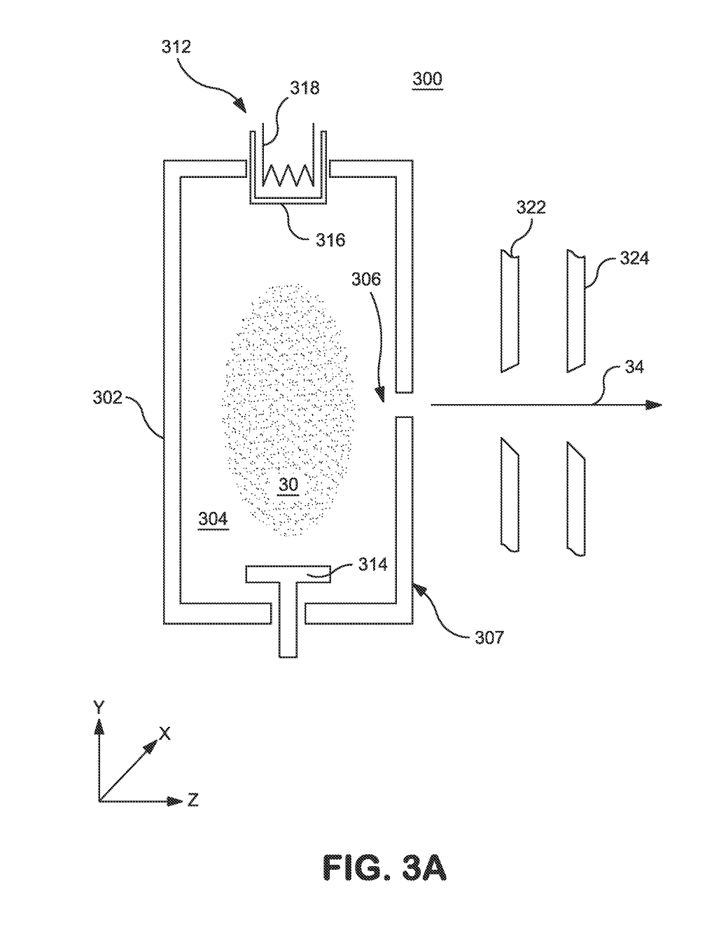

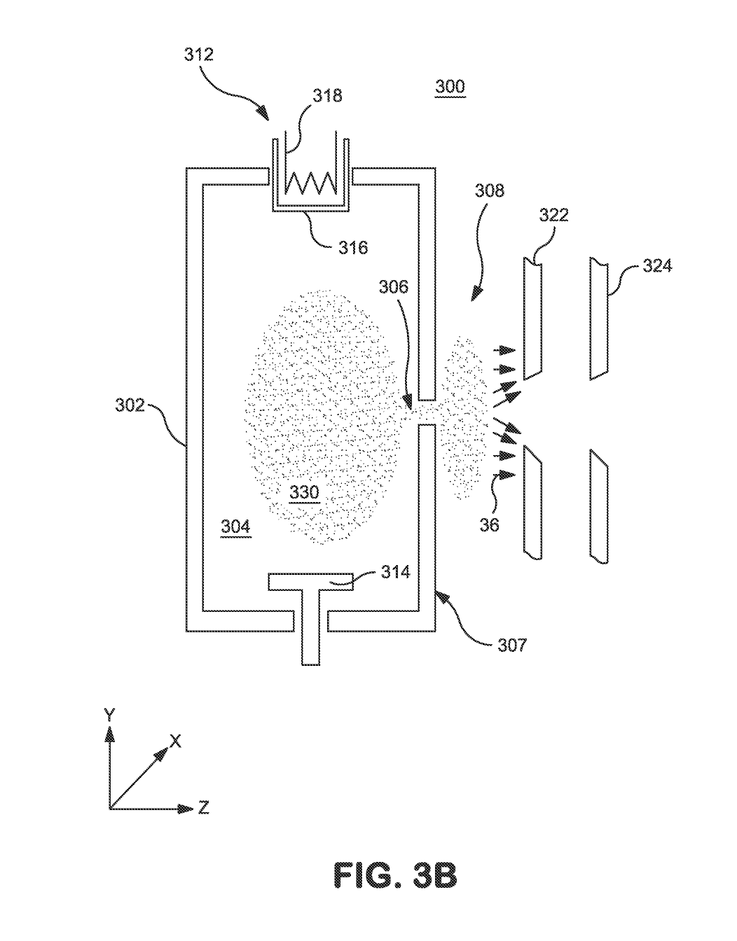

FIG. 3A shows several components of a representative ion implanter, including an ion source 300. In the present embodiment, glitching may occur in the ion source 300 of the ion implanter. The ion source 300 may comprise an arc chamber body 302 defining the arc chamber 304, within which plasma 30 is contained.

One or more of the chamber walls of the arc chamber body 302 may be made of a conductive material such that a bias voltage may be applied to these chamber walls. One of these conductive chamber walls, referred to as the faceplate 307, includes the extraction aperture 306, through which ions generated within the arc chamber 304 may pass. These ions are directed toward a workpiece through the use of beam optics.

As stated above, the arc chamber body 302 contains an extraction aperture 306 within which ions may be extracted from the arc chamber 304. The ion source 300 may also comprise a source for generating a plasma. In the present embodiment, the source for generating the plasma may be an indirectly heated cathode (IHC) 312 and a repeller 314. Although the present embodiment focuses on an IHC based ion source, the present disclosure does not preclude other types of plasma generators, including RF based ion source, Electron-Cyclotron-Resonance (ECR) style ion source, Helicon ion source, or Freeman type ion source. The indirectly heated cathode, if included, may comprise a cathode 316 and a filament 318.

Proximate to the extraction aperture 306, there may be a suppression electrode 322 and a ground electrode 324. Each of the suppression electrode 322 and the ground electrode 324 may contain an aperture that is aligned with the extraction aperture 306 of the arc chamber body 302. The suppression electrode 322 and the ground electrode 324 are collectively referred to as the extraction electrodes and comprise the beam optics.

During an implant mode, the ions of desired implant species are generated in the ion source 300. To generate the ions, a processing material containing the desired species is introduced into the ion source 300, where the material is ionized and the plasma 30 containing the ions is generated. Preferably, a processing material in gaseous or vapor form is used. However, the present disclosure does not preclude introducing the processing material in a solid form into the ion source 300.

Generally, the processing material may contain one or more different species. However, the present disclosure does not preclude the processing material comprising only one species. If two or more species are included in the processing material, at least one species may be the implant species. Meanwhile, one other species in the processing material may be implant species carrier. The implant species carrier may be the species that is preferably not implanted into the target downstream of the ion source 300. However, those of ordinary skill in the art will recognize that in some embodiments, the processing material may contain two or more species, and all species are implanted into the target.

In the present disclosure, the desired implant species in the processing material may include species found in Group 13 (also referred to as Group III) to Group 17 (also referred to as Group VII) of the periodic table such as, for example, boron (B), aluminum (Al), gallium (Ga), indium (In), thallium (Tl), carbon (C), silicon (Si), germanium (Ge), tin (Sn), lead (Pb), phosphorous (P), arsenic (As), antimony (Sb), bismuth (Bi), oxygen (O), sulfur (S), selenium (Se), tellurium (Te), bromium (Br), and iodine (I). Those of ordinary skill in the art will recognize that the above examples are not exhaustive, and other species, including other species in other groups, may also be used. Meanwhile, the implant species carrier in the processing material may be species found in Group 1, and Group 15 to Group 17 of the periodic table. Several examples of the implant species carrier in the processing material may include hydrogen (H), nitrogen (N), oxygen (O), fluorine (F), and chlorine (Cl). Much like the examples noted above, the examples of the implant species carrier provided above are not exhaustive, and other species, including other species in other groups, may also be used. Specific examples of the processing materials may include boron trifluoride (BF₃), diborane tetrafluoride (B₂F₄), borane (BH₃), diborane (B₂H₆), carbon monoxide (CO), carbon dioxide (CO₂), methane (CH₄), phosphorus trifluoride (PF₃), phosphine (PH₃), arsenic trifluoride (AsF₃), and arsine (AsH₃). Although various processing materials may be included in the present disclosure, the present disclosure will focus on, for clarity and simplicity, CO, CO₂, and CH₄ as the processing material, where the implant species is C and the implant species carrier is O and/or H. Those of ordinary skill in the art should recognize that other processing materials containing other implant species and/or implant species carriers are not excluded. Moreover, those of ordinary skill in the art will recognize that in some cases, the species described above as the implant species carrier may, in fact, be used as the implant species, or vice versa.

In some cases, one or more non-implant materials are also introduced into the ion source 300. The non-implant materials may include dilutant that, if added, may enhance ionization and promote formation of the plasma containing the ions of the implant species. As discussed below, the non-implant materials may also enhance the lifetime and improve the performance of the ion source 300. In the present disclosure, the non-implant species may include species found in Group 1, and Group 15-18 (also referred to as Groups V through VIII) of the periodic table. Several specific examples of the non-implant materials may include materials containing hydrogen (H); inert species such as nitrogen (N); halogen species such as fluorine (F), chlorine (Cl), bromine (Br), and iodine (I); and noble species such as helium (He), neon (Ne), argon (Ar), krypton (Kr), and xenon (Xe). Those of ordinary skill in the art will recognize that the above examples of the non-implant material or dilutant are not exhaustive, and material containing other species may also be used as the non-implant materials. For clarity and simplicity, the present disclosure will focus on non-implant materials or dilutants containing H₂ and Xe.

To generate the ions, the filament 318 is powered by a power supply (not shown), the cathode 316 thermionically emits electrons that collide with the processing materials. As a result, a plasma 30 containing, among others, the ions of desired implant species and the ions and other chemical fragments of the processing and non-implant materials are generated. The ions of desired implant species are extracted from the arc chamber body 302. During an implant mode, the ions of desired species is directed in the form of an ion beam 34 toward the target and implanted into the target.

During normal operation, chamber walls of the arc chamber body 302 may be biased at an operating extraction bias voltage, such as about +10 kV, equivalent to the desired implant energy. Of course, other voltages may be used and the disclosure is not limited to this embodiment. The suppression electrode 322 may be biased at a much more negative potential, such as about −36 kV volts, also referred to as the operating suppression bias voltage. The ground electrode 324 may be biased at a less negative bias voltage, such as −30 k. This set of bias voltages may be referred to collectively as operating bias voltages. During normal operation, a processing material, such as those described above, which typically contains one or more desired dopants, is fed through a nozzle (not shown) into the arc chamber body 302. The flow rate of this processing gas may be about 5 sccm. The negative voltages applied to the extraction electrodes attract positive ions through the extraction aperture 306 to form an ion beam 34. Of course, other voltages and flow rates may be used and the disclosure is not limited to a particular embodiment.

There are two different methods that can be used to reduce the glitch rate. First, a plasma-assisted conditioning may be performed. This usually takes less than one minute, but can take longer in other embodiments. Plasma is pulled from the ion source into the region of the extraction electrodes and a bias voltage is applied to the extraction electrodes to initiate sputter or chemical cleaning.

During plasma-assisted conditioning, as shown in FIG. 3B, plasma 30 boundary oscillates and expands from within the arc chamber 304 into the extraction region 308 between the extraction aperture 306 and suppression electrode 322. To begin the conditioning, the voltages applied to the suppression electrode 322 and the ground electrode 324 may be modified. For example, in one embodiment, these bias voltages may be much less negative than those used during normal operation. For example, in one embodiment, the suppression electrode 322 may be biased at −6 kV while the ground electrode 324 is biased at 0V. In another embodiment, the bias voltage applied to the suppression electrode 322 may also be 0V. These reduced bias voltages may be ineffective at generating an ion beam. In some embodiments, the plasma generator may be operated in a closed loop manner, such that its power level is modulated based on the measured ion beam current. Thus, in this embodiment, the modification of the bias voltages applied to the suppression electrode 322 and the ground electrode 324 may cause additional power to be supplied to the IHC 312 or other plasma generator as it attempts to maintain the desired ion beam current. This increased power may create a high density plasma within the arc chamber 304. In other embodiments, the IHC 312 or other plasma generator may be operated in an open loop configuration. In this embodiment, the power applied to the IHC 312 may be modulated to create the effect described herein. During the plasma-assisted conditioning, the chamber walls and the faceplate 307 of the arc chamber body 302 may be biased at their operating extraction bias voltage, or may be biased at a different voltage, such as 0V.

This high density plasma with modified extraction bias voltages causes the plasma 30 to oscillate, as the plasma generator attempts to maintain the desired extraction current. This, in turn, causes both the plasma potential and plasma boundary to oscillate. The oscillating plasma forms the oscillating bias voltages in the extraction region 308 (i.e. the region between the faceplate 307 and the suppression electrode 322). The combination of expanded plasma and bias voltages causes ion 36 to bombard the suppression electrode 322. This mechanism is referred to as plasma-assisted conditioning. After the desired duration has elapsed, the bias voltages of the suppression electrode 322 and the ground electrode 324 and the chamber walls of the arc chamber body 302 are returned to their operating voltages, and the ion beam 34 is formed again. This brief interruption may not change the processing material, source condition, or beam optics. Therefore, the original ion beam 34 may be restored in approximately two minutes or less in some instances. In some embodiments, the conditioning is completed in less than one minute. This conditioning may remove some material from the suppression electrode 322 and the ground electrode 324. However, in some embodiments, the short duration and low voltages used during conditioning may not remove a significant amount of material. Rather, the surfaces of the suppression electrode 322 and the ground electrode 324 may only be conditioned, whereby these surfaces may become smoother than before the conditioning began. In other words, small peaks on the surface of the suppression electrode 322, from which arcs typically originate, may be smoothed by the plasma-assisted conditioning. The smoothness of these surfaces may reduce their propensity to arc, thereby reducing the glitch rate. It is possible that the plasma-assisted conditioning may not be able to remove all the material or impact the glitch rate as desired if the material has a certain thickness. In one instance, material with a thickness of approximately 100 microns may be too thick to be totally removed with plasma-assisted conditioning. Of course, changes to the parameters of the plasma-assisted conditioning that can remove thicker material deposits are possible.

In one particular embodiment of plasma-assisted conditioning, when an IHC 312 is used as the plasma generator, the arc current of the IHC 312 used in the ion source 300 is oscillated between 20 and >40 A, which may be up to ˜60 A, while other bias voltages stayed constant, for example, at 0 V. This indicates that the source plasma density, plasma potential and plasma boundary changes over time, causing the source ions to be pulled out toward the extraction region 308 at varying angles. The mechanical oscillation of the ions striking the surfaces of the suppression electrode 322 and the ground electrode 324 with the elevated temperature of the source/extraction may remove some of the materials deposited on the surfaces of these extraction electrodes. This resets the glitch performance, especially during the initial phase of ion beam operation. This may be used specifically with a boron ion beam, such as an ion beam generated from BF₃. This may be due to the chemical ability of fluorine ions to remove previously deposited material from these extraction electrodes.

Second, a plasma-assisted cleaning may be performed. This is usually a cleaning process using an argon plasma to sputter the various surfaces, though other noble gases, other inert species such as Kr or Xe, or other species such as PH₃ may be used. Thus, while cleaning plasma 330 in the plasma-assisted conditioning is created by ionizing the processing material that is used during normal operation, the cleaning plasma 330 in the plasma-assisted cleaning may be created by ionizing a different source gas.

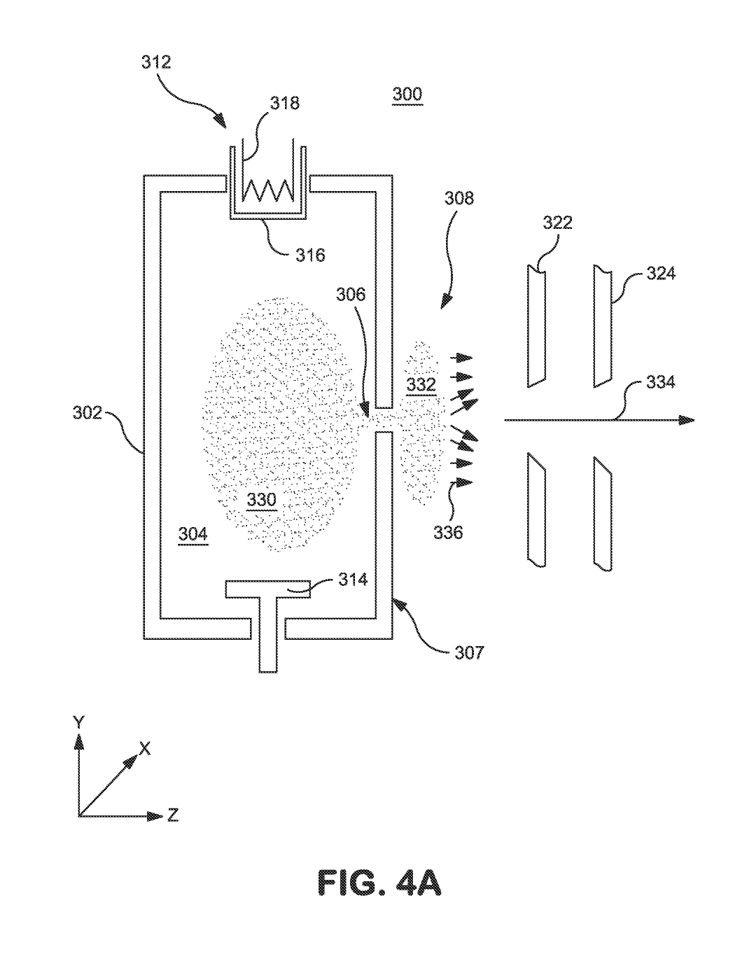

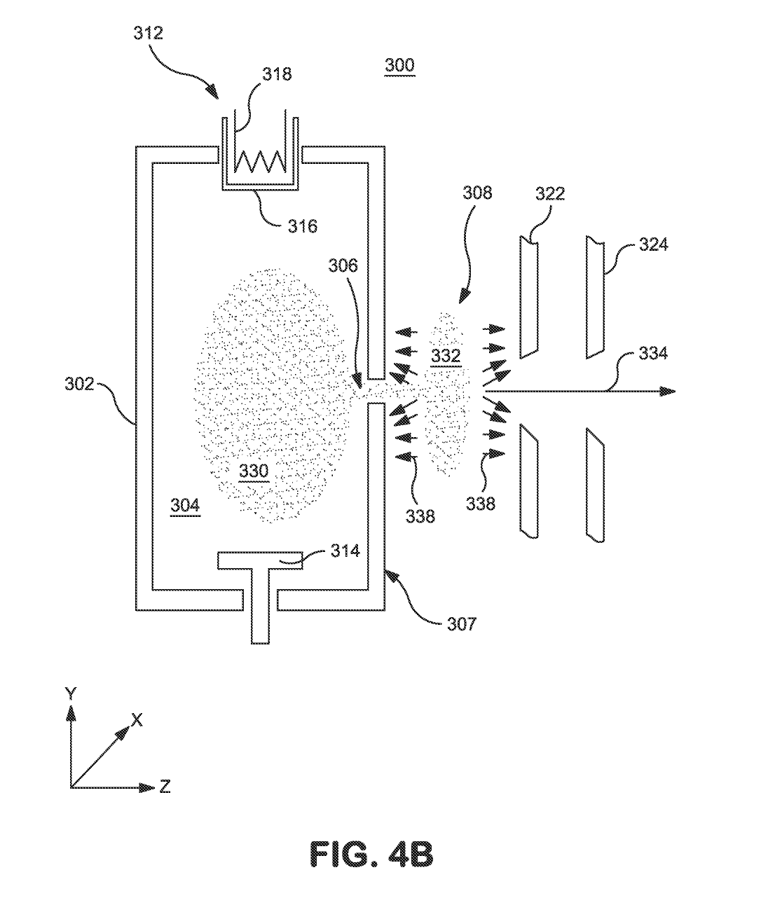

In some embodiments, the processing material may be used during the cleaning process. Plasma-assisted cleaning typically takes between 15 and 60 minutes, but longer or shorter cleaning processes are possible. The additional time compared to the plasma-assisted conditioning may be needed to change source gases and beam optics settings. For example, to reset to the desired implant species, an additional 15 to 60 minutes may be needed. In some embodiments, the plasma-assisted cleaning may involve a change in source gas. As described above, a suitable cleaning gas for plasma-assisted cleaning may comprise a noble gas, such as argon, Kr, or Xe, or a gas such as PH₃. The flow rate of this cleaning gas may be the same as that used in normal operating mode, such as 5 sccm. This is used to create a cleaning plasma 330, as shown in FIG. 4A.

In addition, in some embodiments, the suppression electrode 322 and the ground electrode 324 may be physically moved relative to the arc chamber body 302, as shown in FIG. 4A. In this embodiment, the extraction electrodes may be moved further away from the arc chamber body 302, and specifically from the faceplate 307. For example, during normal operating mode, the suppression electrode 322 may be about 10 mm from the faceplate 307. During plasma-assisted cleaning, this separation distance may be increased to, for example, 22 mm. In addition, as described above with respect to the plasma-assisted conditioning, the bias voltages applied to chamber walls and the faceplate 307 of the arc chamber body 302, the suppression electrode 322 and the ground electrode 324 may be modified. For example, in one embodiment, the ground electrode 324, chamber walls of the arc chamber body 302 and the faceplate 307 may all be biased at 0V. In this mode, the current applied to the suppression electrode 322, referred to as the suppression current, may be maintained at a level equal to or slightly higher than the current supplied to the arc chamber body 302, which is also referred to as the extraction current. The suppression electrode 322 may be negatively biased relative to these components, such as at between −3 kV and −5 kV. Additionally, the power supplied to the IHC 312 or other plasma generator may be modified.

Under this condition, a portion of the cleaning plasma 330 may be extracted from the arc chamber body 302 via the extraction aperture 306, thus generating a high-perveance beam between the faceplate 307 and the suppression electrode 322. It is noted that extraction of a plasma is different than extraction of ions. For example, a plasma includes both ions and electrons, contained within a plasma sheath. Extraction of plasma indicates that all of these components are extracted through the extraction aperture 306. In contrast, when ions are extracted through the extraction aperture 306, it is only the ions that exit the arc chamber 304. The electrons and plasma sheath remain within the arc chamber 304.

The combination of source magnetic field in the extraction region 308 (˜100 gauss or stronger, in the x-direction) and the secondary electrons generated by high-perveance beam provide a favorable condition for generating stable, high-density secondary plasma 332 in the region between arc chamber body 302 and the suppression electrode 322. In addition, the difference between the voltage applied to arc chamber body 302 and the voltage applied to the suppression electrode 322 is reduced in this cleaning mode. This reduction in potential difference reduces the strength of the electrical field in the extraction region 308. In some embodiments, to reduce the electrical field, the difference between the voltage applied to the arc chamber body 302 and the voltage applied to the suppression electrode 322 may be less than 5 kV. In other embodiments, this difference may be less than 2 kV. In some embodiments, the extraction bias voltage may be equal to the suppression extraction voltage to eliminate the electrical field in the extraction region 308. Furthermore, in some embodiments, the electrical field is also reduced by increasing the separation distance between the arc chamber body 302 and the suppression electrode 322.

Due to these conditions, it is easier for the cleaning plasma 330 to leak through the extraction aperture 306. Thus, this high-density secondary plasma 332 may be an extension of the cleaning plasma 330 within the arc chamber body 302. The ions 336 from the secondary plasma 332 may be directed toward the suppression electrode 322 and sputter any material formed thereon. The combination of high-perveance beam 334 and the sputtering by the ions 336 from the secondary plasma 332 may provide an effective cleaning of the suppression electrode 322. By removing excessive formation of the material formed on the suppression electrode 322 and cleaning the suppression electrode 322, excessive glitching may be avoided.

While longer in duration than the plasma-assisted conditioning, plasma-assisted cleaning may remove deposits from the suppression electrode 322 and the ground electrode 324 that plasma-assisted conditioning may be unable to remove or may be unable to remove in a reasonable time. Since plasma-assisted cleaning may use a sputtering mechanism, the effects may be proportional to energy, density, and time. In one particular embodiment, the sputtered material coats the front surface of the suppression electrode 322 (i.e. the surface that faces the extraction aperture 306), which covers particles that have deposited on that surface and that could otherwise contribute to an increased glitch rate.

The plasma-assisted cleaning process illustrated in FIG. 4A differs from the plasma-assisting conditioning process illustrated in FIG. 3B in at least one of two ways. First, in some embodiments, the source gas is changed in the plasma-assisted cleaning process, such that a cleaning gas, such as a noble gas or PH₃ or AsH₃, is used. As described above, in the plasma-assisted conditioning process, the processing material is used. Second, in some embodiments, the extraction electrodes are moved relative to the faceplate 307 in the plasma-assisted cleaning process. As described above, the separation between the faceplate 307 and the suppression electrode 322 may increase from about 10 mm to about 22 mm in this mode.

FIG. 4B illustrates a second embodiment of plasma-assisting cleaning. In the present embodiment, glitching may occur between faceplate 307 and suppression electrode 322 of the ion implanter. Those of ordinary skill in the art will realize that several features illustrated in FIG. 4B are also illustrated in FIG. 3A. As such, FIG. 4B should be understood in relation to FIG. 3A.

In the present embodiment, the material formed on the faceplate 307, especially near the extraction aperture 306, may be removed by applying an extraction current that is more negative, for example, twice as negative, than the suppression current. In this configuration, a high-density cleaning plasma 330 is generated inside the arc chamber 304. The cleaning plasma 330 may be generated using an IHC 312 or other plasma generator. The arc chamber body 302 may be maintained at about −1 to −3 kV. Meanwhile, the suppression electrode 322 may be maintained at −1 to −4 kV. In other words, the difference between the bias voltages applied to the arc chamber body 302 and the suppression electrode 322 is reduced, thereby weakening the electric field in the extraction region 308. The ground electrode 324 may be maintained at a reference potential, such as 0V. Under these conditions, a portion of the cleaning plasma 330 may be extracted from the arc chamber body 302 via the extraction aperture 306 and may also generate high-perveance beam 334 in the region between the arc chamber body 302 and the suppression electrode 322. The source magnetic field in the extraction region (˜100 gauss or stronger, in x-direction) and the secondary electrons provide favorable conditions for generating a stable secondary plasma 332 in the extraction region 308.

Thereafter, the secondary plasma 332 may be referenced to the ground electrode 324, thus provide potential difference between secondary plasma 332 and the ground electrode 324. The voltage difference between the secondary plasma 332 and the arc chamber body 302 may induce the ions in the secondary plasma 332 to be directed toward the arc chamber body 302, especially toward the faceplate 307 nearby the extraction aperture 306. The ions 338 may sputter the materials formed near the extraction aperture 306 to remove the material from the faceplate 307 of arc chamber body 302 near the extraction aperture 306.

In a further embodiment, the voltage applied to the chamber walls of the arc chamber body 302 may be modulated to modify the plasma-assisted cleaning process. For example, the arc chamber body 302 may be biased at a first extraction bias voltage to allow a high-density cleaning plasma 330 to extend outside the arc chamber 304 to the region between faceplate 307 and suppression electrode 322. This first extraction bias voltage may be, for example, between −1 kV and −3 kV. The suppression electrode 322 may be biased at a first suppression bias voltage at this time, while the ground electrode 324 may be grounded. This first suppression bias voltage may be, for example, between about −1 kV and −4 kV. As described above, a high-density cleaning plasma 330 may leak out of the extraction aperture 306 and into the extraction region 308. If the first suppression bias voltage is more negative that the first extraction bias voltage, positive ions will be drawn to the suppression electrode 322 and may initiate cleaning of the suppression electrode 322. The secondary plasma 332 is referenced to this first extraction bias voltage. Thereafter, a second extraction bias voltage, more negative than the first extraction bias voltage, may be used to bias chamber walls of the arc chamber body 302. This more negative voltage attracts ions from the secondary plasma 332 toward the faceplate 307, thereby initiating cleaning of the faceplate 307. In some embodiments, this second extraction bias voltage may be more negative than the first suppression bias voltage. In other embodiments, this second extraction bias voltage may be equal in magnitude to the first suppression bias voltage. This sequence can be repeated a plurality of times, such that the extraction electrodes 322, 324 and the faceplate 307 are both cleaned. In some embodiments, the extraction bias voltage is modulated at a frequency of between 1 kHz and 100 kHz.

In a further embodiment, the voltages applied to the suppression electrode 322 and the chamber walls of the arc chamber body 302 are both modulated, while the ground electrode 324 may be grounded. For example, in one embodiment, the first extraction bias voltage may be between −500V and −1 kV and the first suppression bias voltage may also be in this range. A plasma is generated in high density mode, as described above. This configuration provides some cleaning or conditions of the suppression electrode 322 and the faceplate 307. At a later time, a second extraction bias voltage, more negative than the first extraction bias voltage is applied to the chamber walls of the arc chamber body 302. Similarly, a second suppression bias voltage, more negative than the first suppression bias voltage is applied to the suppression electrode 322. For example, the second extraction bias voltage and the second suppression bias voltage may both be about −3 kV. This configuration provides good sputtering on both the extraction electrodes and the faceplate 307. This sequence of steps can be repeated to repetitively pull secondary plasma 332 from the arc chamber 304 and then perform the plasma-assisted cleaning. As described above, the extraction bias voltage may be modulated at a frequency of between 1 kHz and 100 kHz.

In some embodiments, this second type of plasma-assisted cleaning, using a modulated extraction bias voltage, may be done using the processing material. In other embodiments, a cleaning gas, such as argon, Kr, Xe or PH₃, AsH₃, may be used. In addition, the extraction electrodes may be moved away from the faceplate 307. In some embodiments, the beam optics are moved so that the suppression electrode is 22 mm away from the faceplate 307, as compared to its nominal distance of about 10 mm.

In other words, two different methods of resetting the glitch performance in the extraction region 308 are disclosed. The first method, referred to as plasma-assisted conditioning, conditions the extraction electrodes through the manipulation of source plasma 30, by modifying the power supplied to the plasma generator, and by modifying the bias voltages applied to the arc chamber body 302 and the suppression electrode 322 and the ground electrode 324. During this method, the source gas is not modified, allowing quick transition back to operating mode. The second method, referred to as plasma-assisted cleaning, changes the voltages applied to the various components, as was done in the conditioning mode. However, at least one additional modification is made. For example, the source gas from which the plasma is created may be changed to increase the ability to remove material from the extraction electrodes. In addition, the physical location of the extraction electrodes may be modified to allow a more complete cleaning. Furthermore, in some embodiments of the plasma-assisted cleaning, the voltage applied to the chamber walls of the arc chamber body 302 may be negative to attract ions from the plasma toward the faceplate 307.

In one experiment using a B⁺ ion beam, performing a one minute plasma-assisted conditioning reduced the glitch rate from 67 per hour to 30 per hour. Performing a one hour argon plasma-assisted cleaning reduced the glitch rate for a B⁺ ion beam from 80 per hour to 38 per hour. In another test, the glitch rate was reduced was about 34 per hour to about 8 per hour. The benefits using each method may be compared to the relative duration to perform each or the relative throughput impact for each.

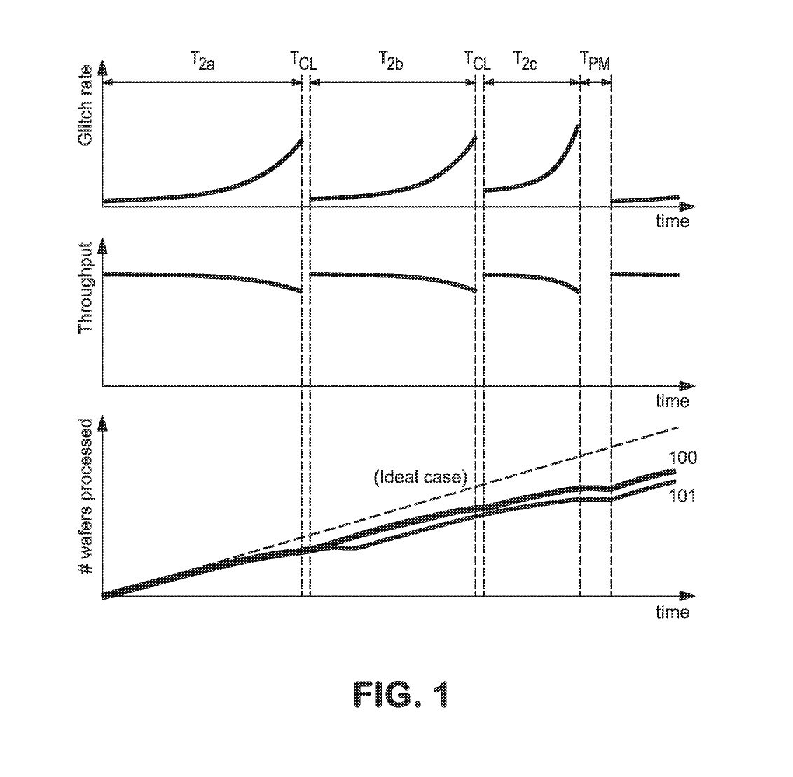

FIG. 1 shows charts representing glitch rate, throughput, and number of wafers processed over time in a first embodiment. In this embodiment, a plasma-assisted cleaning is performed at times T_{CL}. T_{PM} represents preventative maintenance of the ion source 300 and extraction electrodes, which may take between three and four hours in one instance.

In one embodiment, preventative maintenance involves venting the arc chamber, cleaning or replacing parts in the ion source 300, pumping the arc chamber back to vacuum, and then calibrating the ion beam 34. Line 100 represents the number of wafers processed using the method illustrated in FIG. 1. T₂ₐ through T_{2c} represent continuous beam operation periods between cleanings (i.e. the mode of operation shown in FIG. 3A). In some embodiments, the durations of T₂ₐ through T_{2c} are predetermined. For example, the durations of the continuous beam operation periods may be based on operating parameters, such as the type of processing material used and the desired ion beam current. In a further embodiment, the duration of each continuous beam operation period is shorter than the preceding one. This may be due to the fact that the cleanings may not remove all of the material from the extraction electrodes, so material buildup occurs more quickly each time. In other embodiments, the initiation of cleanings may be determined based on a glitch detector. In this way, a cleaning is performed whenever the glitch rate exceeds a predetermined rate. Thus, there is no predetermined time period associated with the continuous beam operation periods, T₂ₐ through T_{2c}.

As a comparison, line 101 represents the number of wafers processed if only preventative maintenance is performed without the plasma-assisted cleaning. Note that without the periodic cleanings, the overall throughput decreases, as the glitch rate continues to increase. For example, even through no workpieces are processed during the cleanings, the overall throughput using the plasma-assisted cleaning (line 100) is still greater than the throughput using only preventative maintenance (line 101). In addition, the overall down time with two T_{CL} may be shorter than with one T_{PM}.

As another example, consider a boron beam current operated at 60 mA. In this case, the source should be replaced in every 60 hours, which takes ˜3 hours to go back to full operation. With the plasma-assisted cleaning, the source can last 120 hours with less than 1 hour of total interruption. As a result, the tool uptime could be improved from 95% to 97%.

In some embodiments, the preventative maintenance is performed at fixed time intervals, such as every 96 hours. In other embodiments, the preventative maintenance may be performed after every N cleanings, where N is a configurable value. In the example shown in FIG. 1, N is assigned a value of 2. In yet another embodiment, the preventative maintenance may be performed if the duration of the previous continuous beam operation period (i.e. T_{2c}) is less than a predetermined threshold. This embodiment may be used when continuous beam operation is determined based on glitch rate. In other words, if the duration between the end of the previous cleaning and the time when the glitch rate exceeds its predetermined threshold is too short, it may be assumed that the cleanings are no longer effective. In this case, a preventative maintenance may be performed. In another embodiment, preventative maintenance may be initiated based on the operating conditions of the ion implanter. For example, in one embodiment, once the glitch rate exceeds a predetermined threshold or the throughput drops below a predetermined threshold, preventative maintenance may be scheduled.

Furthermore, it is also noted that, although not shown, the throughput achieved by more frequent preventative maintenance may be less than that shown in line 100. For example, performing a preventative maintenance instead of a plasma-assisted cleaning, may reduce the overall throughput due to the long duration of T_{PM}, as compared to T_{CL}. In other words, although a preventative maintenance may be more effective at removing material from the extraction electrodes than a plasma-assisting cleaning, its long duration may ultimately reduce throughput.

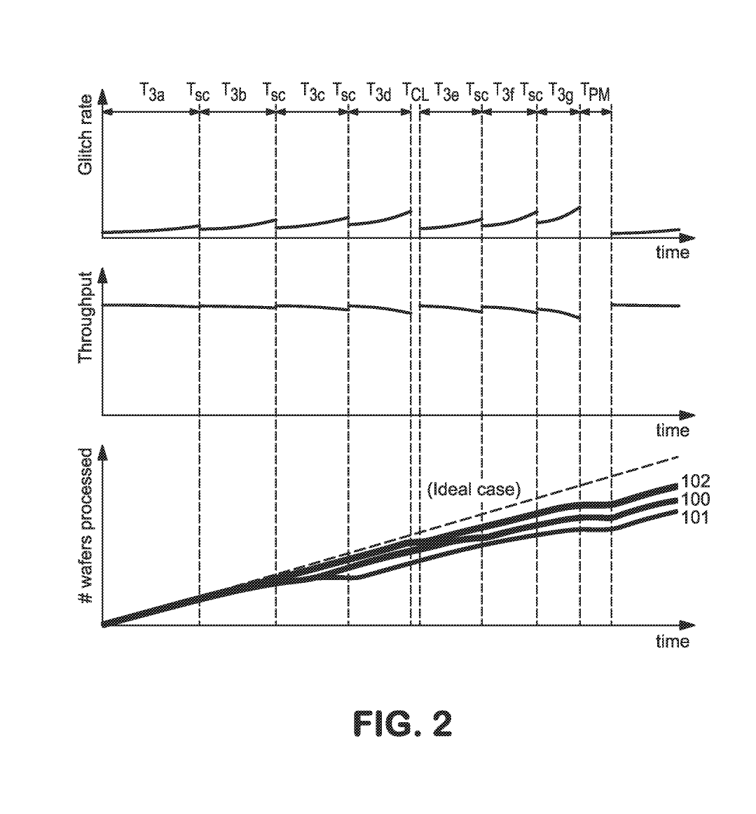

FIG. 2 shows charts representing glitch rate, throughput, and number of wafers processed over time in a second embodiment. This embodiment uses a combination of plasma-assisted conditioning and plasma-assisted cleaning. The plasma-assisted cleaning is represented by T_{CL} and the plasma-assisted conditioning is represented by T_{SC}. T₃ₐ through T_{3g} represent continuous beam operation periods between conditionings or cleanings (i.e. the mode of operation shown in FIG. 3A). Plasma-assisted conditioning can remove some material buildups on the extraction electrodes and can be combined with a plasma-assisted cleaning. A combination of these two methods can be combined to increase throughput and the number of wafers processed. Line 102 represents the number of wafers processed using this method combining the plasma-assisted cleaning and plasma-assisted conditionings illustrated in FIG. 2. Line 102 may be compared to line 101 or line 100 from FIG. 1. As seen in FIG. 2, the combination method shown with line 102 provides the highest number of processed wafers. Use of plasma-assisted conditioning may only take one to two minutes, which has a significantly smaller impact on throughput than a plasma-assisted cleaning.

In some embodiments, the plasma-assisted conditioning occurs at predetermined time intervals. In some further embodiments, these time intervals may decrease for each subsequent continuous beam operation period. This may be due to the fact that the conditionings may not remove all of the material from the extraction electrodes, so material buildup occurs more quickly each time. In other embodiments, the plasma-assisted conditioning is initiated by detection of a glitch rate that exceeds a predetermined threshold.

In some embodiments, a plasma-assisted cleaning occurs after a predetermined number of plasma-assisted conditionings have been performed. In another words, a plasma-assisted cleaning may occur after N plasma-assisted conditionings, where N is a configurable value. In another embodiment, the plasma-assisting conditionings are initiated based on glitch rate. In this embodiment, a plasma-assisted cleaning may be initiated when the time between two successive plasma-assisted conditionings is less than a predetermined time. This may imply that the conditionings have become ineffective at removing sufficient material from the extraction electrodes to lower the glitch rate. Furthermore, in this embodiment, the preventative maintenance may be initiated when the time between two plasma-assisted cleanings is less than a predetermined time. Alternatively, the preventative maintenance may be initiated based on the time between two plasma-assisted conditionings.

In other embodiments, preventative maintenance may be performed after a specific number of cleanings or a specific number of conditionings and cleanings. In yet another embodiment, preventative maintenance may be performed after a specified time duration, such as 96 hours and is not affected by the number or frequency of the cleanings and conditionings.

In the specific embodiment of FIG. 2, three plasma-assisted conditioning steps are performed prior to a plasma-assisted cleaning. This cycle of three plasma-assisted conditionings and a plasma-assisted cleaning is repeated twice. However, the second time the plasma-assisted cleaning is replaced with preventative maintenance. Of course, other variations or combinations of these steps are possible and FIG. 2 is merely illustrated as an example. For example, additional plasma-assisted conditionings may be performed with a similar number of plasma-assisted cleanings or preventative maintenance steps.

While the above describes the use of both plasma-assisted conditioning and plasma-assisted cleaning, it is also noted that, in some embodiments, plasma-assisted cleaning is performed when the glitch rate reaches a predetermined value, without the use of plasma-assisted conditioning.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. These other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A method of reducing a glitch rate of an ion implanter, comprising:
generating a plasma in an arc chamber, defined by an arc chamber body;
extracting plasma from said arc chamber body through an extraction aperture disposed on a faceplate of said arc chamber to an extraction region outside said arc chamber; and
directing ions within said plasma disposed in said extraction region toward said faceplate.

2. The method of claim 1, wherein said extracting plasma from said arc chamber body is achieved by:
generating a high density plasma within said arc chamber;
applying a first extraction bias voltage to said arc chamber body; and
applying a first suppression bias voltage to a suppression electrode disposed outside and proximate said faceplate, said first suppression bias voltage selected based on said first extraction bias voltage so as to reduce a strength of an electrical field disposed in said extraction region.

3. The method of claim 1, wherein said directing ions within the plasma disposed in said extraction region toward said faceplate is achieved by:
changing a bias voltage applied to said arc chamber body from a first extraction bias voltage, used to generate said plasma, to a second extraction bias voltage, said second extraction bias voltage being more negative than said first extraction bias voltage.

4. The method of claim 1, further comprising:
impacting ions within said plasma disposed in said extraction region onto a surface of a suppression electrode disposed proximate to said extraction region, said extraction region being disposed between said suppression electrode and said faceplate.

5. The method of claim 4, wherein said impacting ions onto a surface of said suppression electrode is achieved by changing a bias voltage applied to said suppression electrode from a first suppression bias voltage, used to generate and extract said plasma, to a second suppression bias voltage, more negative than said first suppression bias voltage.

6. The method of claim 3, further comprising:
impacting ions within the plasma disposed in the extraction region onto a surface of a suppression electrode disposed proximate to said extraction region, said extraction region being disposed between said suppression electrode and said faceplate, further comprising:
biasing said suppression electrode at a first suppression bias voltage while said arc chamber body is biased at said first extraction bias voltage so as to generate and extract said plasma; and
biasing said suppression electrode to a second suppression bias voltage, more negative than said first suppression bias voltage, while said arc chamber body is biased at said second extraction bias voltage.

7. The method of claim 2, wherein said first extraction bias voltage is a negative voltage.

8. The method of claim 3, wherein a bias voltage applied to said arc chamber is modulated between said first extraction bias voltage and said second extraction bias voltage at a frequency of between 1 kHz and 100 kHz.

9. The method of claim 1, wherein said plasma is created by ionizing argon or an inert gas.

10. A method of reducing a glitch rate of an ion implanter, the method comprising:
generating a plasma in an arc chamber defined by an arc chamber body, said arc chamber body further comprising a faceplate;
extracting first ions within the plasma disposed in said arc chamber through an extraction aperture in said faceplate;
directing said first ions through an aperture of a suppression electrode, said suppression electrode disposed proximate to said arc chamber body; and
extracting a cleaning plasma generated in said arc chamber through said extraction aperture into an extraction region interposed between said faceplate and said suppression electrode.

11. The method of claim 10, further comprising:
directing second ions within said cleaning plasma disposed in said extraction region toward said faceplate.

12. The method of claim 10, further comprising:
impacting second ions within said cleaning plasma disposed in said extraction region onto a surface of said suppression electrode.

13. The method of claim 10, wherein said extracting said first ions within said plasma disposed in said arc chamber and directing said first ions comprises:
applying an operating extraction bias voltage to said arc chamber body, and
applying an operating suppression bias voltage to said suppression electrode, and
wherein said extracting a cleaning plasma into said extraction region comprises:
applying a first extraction bias voltage to said arc chamber body, said first extraction bias voltage being more negative than said operating extraction bias voltage,
applying a first suppression bias voltage to said suppression electrode, said first suppression bias voltage selected based on said first extraction bias voltage so as to reduce a strength of an electrical field disposed in said extraction region.

14. The method of claim 13, further comprising:
directing second ions within said cleaning plasma disposed in said extraction region toward said faceplate;
wherein said directing second ions within said cleaning plasma disposed in said extraction region toward said faceplate comprises applying a second extraction bias voltage to said arc chamber body, wherein said second extraction bias voltage is more negative than said first extraction bias voltage.

15. The method of claim 13, further comprising:
impacting second ions within said cleaning plasma disposed in said extraction region onto a surface of said suppression electrode;
wherein said impacting second ions within said cleaning plasma disposed in said extraction region onto a surface of said suppression electrode comprises applying a second suppression bias voltage to said suppression electrode, said second suppression bias voltage being more negative than said first suppression bias voltage.

16. The method of claim 11, wherein said extracting said cleaning plasma is performed after said extracting said first ions.

17. The method of claim 16, further comprising:
monitoring a glitch rate of said ion implanter, wherein extracting said cleaning plasma generated in said arc chamber through said extraction aperture into said extraction region is performed after said glitch rate exceeds a predetermined level.

18. The method of claim 11, further comprising:
increasing a distance between said faceplate and said suppression electrode.

19. A method of reducing a glitch rate of an ion implanter, the method comprising:
generating a cleaning plasma in an arc chamber, defined by an arc chamber body, said arc chamber body further comprising a faceplate;
extracting said cleaning plasma generated within said arc chamber into an extraction region interposed between said arc chamber body and a suppression electrode; and
impacting a surface of at least one of said faceplate and said suppression electrode with first ions from said cleaning plasma disposed in said extraction region.

20. The method of claim 19, further comprising:
generating a plasma within said arc chamber;
extracting second ions in said plasma disposed within said arc chamber through an extraction aperture in said faceplate; and
directing said second ions from said arc chamber through an aperture of said suppression electrode, said suppression electrode disposed proximate to said faceplate, wherein said first ions and said second ions contain different species.
